(19) United States
(12) Patent Application Publication
(10) Pub. No.: US 2025/0322507 A1
(43) Pub. Date: Oct. 16, 2025

(54) METHOD, DEVICE, AND PRODUCT FOR DETECTING CIRCUIT BOARD

(71) Applicant: Dell Products L.P., Round Rock, TX (US)

(72) Inventors: Zijia Wang, London (GB); Zhen Jia, Shanghai (CN); Bin He, Shanghai (CN); Jinpeng Liu, Shanghai (CN)

(21) Appl. No.: 18/675,327

(22) Filed: May 28, 2024

(30) Foreign Application Priority Data
Apr. 12, 2024 (CN) 202410444894.7

(51) Int. Cl. G06T 7/00; G06T 7/11

(52) U.S. Cl. CPC G06T 7/0004; G06T 7/11; G06T 2207/20081; G06T 2207/30141

(57) ABSTRACT

The present disclosure relates to a method, a device, and a computer program product for detecting a circuit board defect. The method includes acquiring a circuit board image of the circuit board. The method further includes determining a first defect region according to the circuit board image, wherein the first defect region indicates a location of a defect in the circuit board. The method further includes determining a second defect region according to the circuit board image and a standard image for the circuit board, wherein the second defect region indicates a location of a defect in the circuit board, and the standard image indicates a circuit board without any defect. The method further includes determining a defect region of the circuit board according to the first defect region and the second defect region. Accordingly, the accuracy of detecting the defect region on the circuit board can be improved.

### RELATED APPLICATION

The present application claims priority to Chinese Patent Application No. 202410444894.7, filed Apr. 12, 2024, and entitled “Method, Device, and Product for Detecting Circuit Board,” which is incorporated by reference herein in its entirety.

### FIELD

The present disclosure relates to the field of computers, and more particularly, to a method, a device, and a computer program product for circuit board defect detection.

### BACKGROUND

In the manufacturing process of circuit boards, defect detection is a crucial step in ensuring product quality and reliability. Traditional circuit board defect detection methods mainly rely on manual visual inspection, but these methods have problems such as low detection efficiency, low accuracy, and susceptibility to human factors. With the continuous progress of technologies, especially the rapid development of artificial intelligence technologies, neural networks are widely used in various complex pattern recognition tasks, providing new solutions for circuit board defect detection.

The neural network is a computational model that simulates a nervous system of the human brain, and can automatically extract features and make decisions by learning a large amount of data. In the field of circuit board defect detection, the application of neural networks mainly focuses on deep learning techniques, especially convolutional neural networks. The convolutional neural network, by simulating a working mode of a human visual system, can automatically learn deep-level features of a circuit board image and achieve precise locating and recognition of defect regions.

### SUMMARY

Embodiments of the present disclosure provide a method, a device, and a computer program product for detecting a circuit board defect.

In a first aspect of embodiments of the present disclosure, a method for detecting a circuit board defect is provided. The method includes acquiring a circuit board image of a circuit board. The method further includes determining a first defect region according to the circuit board image, wherein the first defect region indicates a location of a defect in the circuit board. The method further includes determining a second defect region according to the circuit board image and a standard image for the circuit board, wherein the second defect region indicates a location of a defect in the circuit board, and the standard image indicates a circuit board without any defect. The method further includes determining a defect region of the circuit board according to the first defect region and the second defect region.

In a second aspect of embodiments of the present disclosure, an electronic device is provided. The electronic device includes at least one processor, and a memory coupled to the at least one processor and having instructions stored therein, wherein the instructions, when executed by the at least one processor, cause the electronic device to perform actions including acquiring a circuit board image of a circuit board. These actions further include determining a first defect region according to the circuit board image, wherein the first defect region indicates a location of a defect in the circuit board. These actions further include determining a second defect region according to the circuit board image and a standard image for the circuit board, wherein the second defect region indicates a location of a defect in the circuit board, and the standard image indicates a circuit board without any defect. These actions further include determining a defect region of the circuit board according to the first defect region and the second defect region.

In a third aspect of embodiments of the present disclosure, a computer program product is provided, the computer program product being tangibly stored on a non-transitory computer-readable medium and including machine-executable instructions, wherein the machine-executable instructions, when executed by a machine, cause the machine to perform actions including acquiring a circuit board image of a circuit board. These actions further include determining a first defect region according to the circuit board image, wherein the first defect region indicates a location of a defect in the circuit board. These actions further include determining a second defect region according to the circuit board image and a standard image for the circuit board, wherein the second defect region indicates a location of a defect in the circuit board, and the standard image indicates a circuit board without any defect. These actions further include determining a defect region of the circuit board according to the first defect region and the second defect region.

It should be noted that this Summary is provided to introduce a series of concepts in a simplified manner, and these concepts will be further described in the Detailed Description below. The Summary is neither intended to identify key features or necessary features of the present disclosure, nor intended to limit the scope of the present disclosure.

### BRIEF DESCRIPTION OF THE DRAWINGS

The above and other features, advantages, and aspects of embodiments of the present disclosure will become more apparent with reference to the accompanying drawings and the following Detailed Description. In the accompanying drawings, identical or similar reference numerals represent identical or similar elements, in which:

FIG. 1 is a schematic diagram of an example environment in which embodiments of the present disclosure can be implemented;

FIG. 2 is a flow chart of a method for detecting a circuit board defect according to some embodiments of the present disclosure;

FIG. 3 is a flow chart of determining a first defect region according to an embodiment of the present disclosure;

FIG. 4 is a schematic diagram of determining a first defect region by using a multi-scale detection network according to an embodiment of the present disclosure;

FIG. 5 is a schematic diagram of a codec according to an embodiment of the present disclosure;

FIG. 6 is a schematic diagram of a method for detecting a circuit board defect according to an embodiment of the present disclosure;

FIG. 7 is a schematic diagram of a method for detecting a circuit board defect according to an embodiment of the present disclosure; and

FIG. 8 is a block diagram of a device that can implement a plurality of embodiments of the present disclosure.

### DETAILED DESCRIPTION

Illustrative embodiments of the present disclosure will be described below in further detail with reference to the accompanying drawings. Although the accompanying drawings show some embodiments of the present disclosure, it should be understood that the present disclosure may be implemented in various forms, and should not be construed as being limited to the embodiments stated herein. Rather, these embodiments are provided for understanding the present disclosure more thoroughly and completely. It should be understood that the accompanying drawings and embodiments of the present disclosure are for exemplary purposes only, and are not intended to limit the scope of protection of the present disclosure.

In the description of embodiments of the present disclosure, the term “include” and similar terms thereof should be understood as open-ended inclusion, that is, “including but not limited to.” The term “based on” should be understood as “based at least in part on.” The term “an embodiment” or “the embodiment” should be understood as “at least one embodiment.” The terms “first,” “second,” and the like may refer to different or identical objects. Other explicit and implicit definitions may also be included below.

In related technologies, there is a solution that utilizes a neural network for performing feature extraction and classification on a circuit board image, and determining where there is a defect on a circuit board according to the classification result. Pre-processing, such as denoising and enhancement, may further be performed on the circuit board image to improve the image quality. Such research has to some extent improved the efficiency and accuracy of circuit board defect detection, but there are still some challenges.

First, the complexity of the circuit board image poses challenges to training of the neural network. The circuit board image is different from other images in that it has a large size, and the defective part only accounts for a small part of the image. The layout of elements on the circuit board is dense, with a wide variety of types and different forms of defects, such that it is difficult for a model to accurately recognize a defect. Second, real-time requirements are also an important consideration factor for the circuit board defect detection. On a production line, it is necessary to conduct rapid and accurate detection of circuit boards to ensure production efficiency and product quality. However, some neural networks in related technologies suffer from a high computational burden and a long time when processing large amounts of data, such that it is difficult to meet real-time requirements.

Therefore, the present disclosure provides a method for detecting a circuit board defect. In the method of an embodiment of the present disclosure, a type of defect region is determined according to a circuit board image, and a first defect region indicates a location of a defect in the circuit board. Another type of defect region is further determined according to the circuit board image and a standard image (that is, a flawless reference image). Detecting the defect in the circuit board by using the two types of defect regions can enhance the accuracy of detection and reduce the possibility of missed and false detections, so that the determination of a defect location is more reliable.

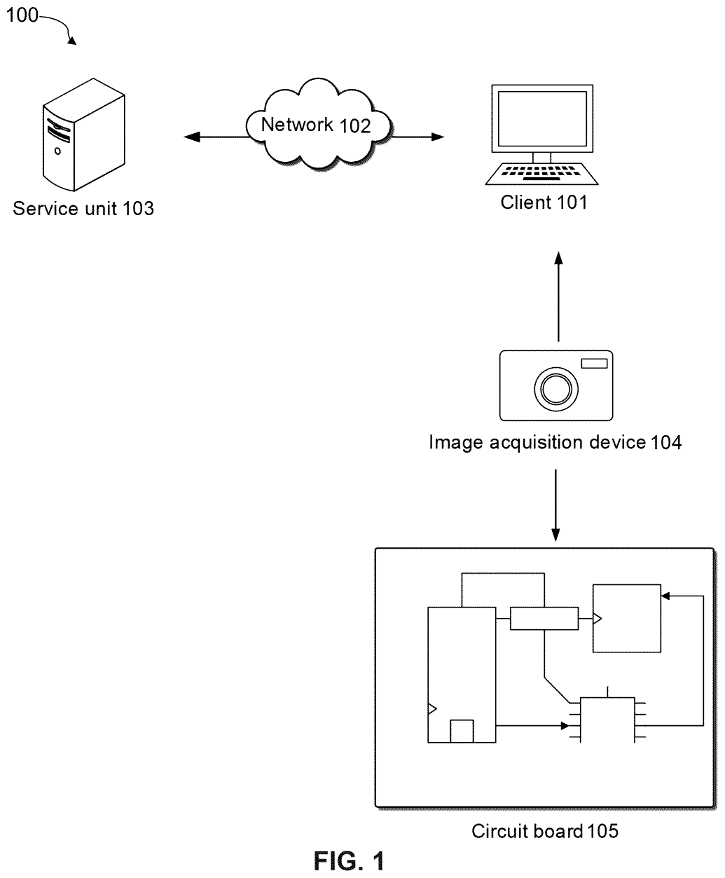

FIG. 1 is a schematic diagram of an example environment 100 in which embodiments of the present disclosure can be implemented. As shown in FIG. 1, the environment 100 may include a client 101, a network 102, a service unit 103, an image acquisition device 104, and a circuit board 105. The service unit 103 is communicatively coupled to the client 101 over the network 102. The network 102 may be, for example, a Wide Area Network (WAN), a Local Area Network (LAN), a wireless network, a public telephone network, an intranet, and any other type of network well known to those skilled in the art.

In some embodiments, the method for detecting a circuit board defect is performed by the service unit 103. The circuit board 105 in FIG. 1, also known as a Printed Circuit Board (PCB), is a support that connects electronic components and circuits together, and is used for realizing functions such as the layout design of complex circuits and electrical signal transmission in electrical and electronic devices. It is usually made of glass fiber as a basic material and processed through processes such as copper coating, gold plating, and etching. It is an example of what is more generally referred to herein as a “circuit board,” and in some embodiments such a circuit board may additionally or alternatively comprise a ceramic circuit board, an alumina ceramic circuit board, an aluminum nitride ceramic circuit board, an aluminum substrate, a high-frequency board, a thick copper board, an impedance board, an ultra-thin wiring board, an ultra-thin circuit board, a printed (copper etching technology) circuit board, and the like.

The image acquisition device 104 is used for capturing an image of the circuit board 105 to serve as a circuit board image. The image acquisition device 104 may be coupled to the client 101 through wired or wireless communication, and may transmit the collected image of the circuit board 105 to the client 101 for preprocessing, such as denoising, enhancement, and other operations, to improve the image quality. The image acquisition device 104 may also be directly coupled to the service unit 103 through wired or wireless communication. The image acquisition device 104 may be a single camera or a multi-camera system, that is, a camera system composed of a plurality of camera subsystems. Each subsystem includes an imaging module and a display module, which can improve the image quality through image fusion of different subsystems.

In some embodiments, the method performed by the service unit 103 includes the following steps. The service unit 103 acquires a circuit board image of the circuit board 105. The service unit 103 may acquire the image of the circuit board 105 from the image acquisition device 104 through the client 101, or directly acquire the image of the circuit board 105 from the image acquisition device 104.

The service unit 103 determines a first defect region according to the circuit board image, wherein the first defect region indicates a location of a defect in the circuit board. The first defect region may be a local region (not shown) in the circuit board 105. In some embodiments, the service unit 103 may pre-store a trained multi-scale detection network, and the multi-scale detection network includes three sub-networks: a feature extraction network, a fusion network, and a prediction network. The feature extraction network is used for determining feature maps at multiple scales of the circuit board image. The fusion network is used for determining fusion features of the feature maps at the multiple scales. The prediction network is used for determining the first defect region. When the service unit 103 determines the first defect region according to the circuit board image, the multi-scale detection network may be directly called to acquire the feature maps at the multiple scales and their fusion features, thereby determining the first defect region.

The service unit 103 determines a second defect region according to the circuit board image and a standard image for the circuit board, wherein the second defect region indicates a location of a defect in the circuit board 105, and the standard image indicates a circuit board without any defect, that is, an intact form of the circuit board 105. The second defect region may be a local region (not shown) in the circuit board 105. In some embodiments, the service unit 103 may also additionally store a pre-trained codec for determining the standard image for the circuit board according to the input circuit board image, which includes an encoder and a decoder. The encoder is used for extracting an image feature, and the decoder is used for reconstructing the standard image according to the image feature.

The service unit 103 determines a defect region of the circuit board according to the first defect region and the second defect region. Detecting the defect in the circuit board by using the two types of defect regions can enhance the accuracy of detection and reduce the possibility of missed and false detections, so that the determination of a defect location is more reliable.

As shown in FIG. 1, in the environment 100, the network 102 may be used to transmit data between the client 101 and the service unit 103. The network 102 has a theoretical bandwidth. The theoretical bandwidth refers to a maximum transmission speed supported by the network 102, which indicates a maximum data amount that may be transmitted by the network 102 in an ideal condition, typically measured by the number of transmitted bits per second (bps). For example, if the theoretical bandwidth of the network 102 is 100 Mbps, it indicates that it may transmit 100 megabits of data per second in an ideal condition. In fact, however, due to other possible factors in the network (such as signal interference, bandwidth sharing, and transmission delay), the actual transmission speed may not reach 100 Mbps.

As understood by those skilled in the art, an example of the service unit 103 may be a stand-alone physical server, a server cluster or a distributed system composed of a plurality of physical servers, or a cloud server that provides basic cloud computing services such as cloud services, cloud databases, cloud computing, cloud functions, cloud storage, network services, cloud communications, middleware services, domain name services, security services, content distribution network (CDN) services, and big data and artificial intelligence platforms. The server may be connected directly or indirectly through wired or wireless communication, which is not limited in the present application.

The client 101 may be any type of mobile computing device, including a mobile computer (such as a personal digital assistant (PDA), a laptop, a tablet, and a netbook), a mobile phone (such as a cellular phone and a smartphone), a wearable computing device (such as a smartwatch, and a head-mounted device including smart glasses and the like), or other types of mobile devices. In some embodiments, the client 101 may also be a fixed computing device, such as a desktop computer, a game machine, and a smart TV.

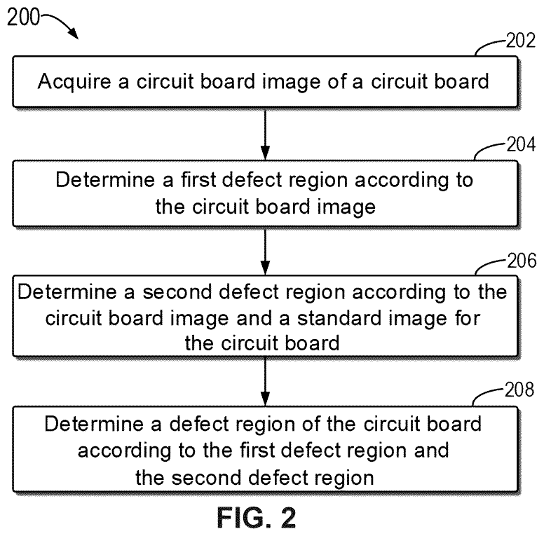

FIG. 2 is a flow chart of a method 200 for detecting a circuit board defect according to some embodiments of the present disclosure. As shown in FIG. 2, the method 200 includes block 202 to block 208. At the block 202, a circuit board image of a circuit board is acquired. For example, the circuit board image to be detected is acquired through a high-definition camera or another image acquisition device. These images should reflect details of the circuit board as clearly as possible for subsequent analysis and processing. Preprocessing may be performed on the circuit board image, for example, applying various filters, such as a median filter and a Gaussian filter, to the circuit board image to reduce noise of the circuit board image.

At block 204, a first defect region is determined according to the circuit board image, wherein the first defect region indicates a location of a defect in the circuit board. A specific algorithm or model may be used for determining the first defect region. The first defect region may include a broken line, an excess solder joint, a missing element, and the like, which directly indicates the location of the defect in the circuit board.

At block 206, a second defect region is determined according to the circuit board image and a standard image for the circuit board, wherein the second defect region indicates a location of a defect in the circuit board, and the standard image indicates a circuit board without any defect. The standard image is used as a reference for comparison with the circuit board image to be detected. By comparing a difference between the two, the second defect region may be determined. In some embodiments, images of several flawless circuit boards may be pre-determined as templates, and then the circuit board image may be compared with the templates to determine the template with the highest similarity as the standard image.

At block 208, a defect region of the circuit board is determined according to the first defect region and the second defect region. According to information on the first defect region and the second defect region, a comprehensive analysis is performed to determine a more reliable defect region of the circuit board. This process may involve operations such as merging, filtering, and refining the two defect regions to obtain a more accurate and reliable detection result. In this embodiment, the type of defects includes but is not limited to a missing hole, a mouse bite, an open circuit, a short circuit, a stray, and fake copper.

In the method of an embodiment of the present disclosure, the first defect region is determined according to the circuit board image, and the first defect region indicates the location of the defect in the circuit board. The second defect region is further determined according to the circuit board image and the standard image (that is, the flawless reference image). Detecting the defect in the circuit board by using the two types of defect regions can enhance the accuracy of detection and reduce the possibility of missed and false detections, so that the determination of a defect location is more reliable.

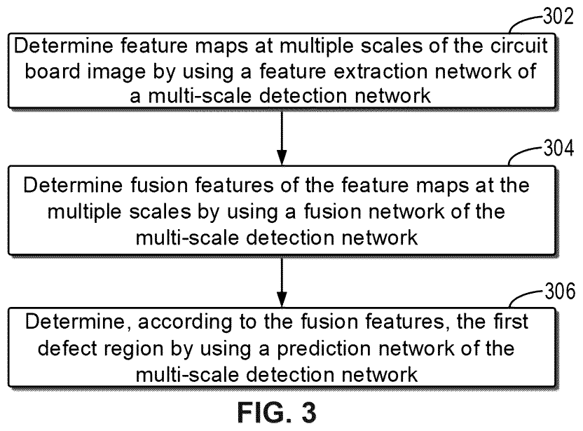

At block 204, the present disclosure further provides an embodiment of determining the first defect region by using a multi-scale detection network. FIG. 3 is a flow chart of determining a first defect region according to an embodiment of the present disclosure, including block 302 to block 306. At block 302, feature maps at multiple scales of the circuit board image are determined by using a feature extraction network of a multi-scale detection network. In some examples, the feature extraction network consists of n concatenated residual blocks, and each residual block includes at least one convolutional layer, wherein n is a positive integer greater than 1. The residual block typically includes a plurality of convolutional layers, a pooling layer, and an activation function layer. By sequentially processing the circuit board image, each residual block may output a feature map, resulting in a total of n feature maps, thereby acquiring feature maps at multiple scales for the circuit board image. In the example, the convolutional layer in the residual block facilitates extracting image features, the pooling layer may prevent overfitting, and therefore, using the residual block to process the circuit board image facilitates accurately extracting image features and eliminating interference information, thereby laying a foundation for improving the detection accuracy.

At block 304, fusion features of the feature maps at multiple scales are determined by using a fusion network of the multi-scale detection network. In some examples, each feature map is cascaded into a feature vector through a convolutional operation. For the convenience of fusion operations, fused objects (that is, the feature maps) should be processed to the same scale. In some examples, upsampling is performed on the second feature vector to the nth feature vector to obtain n−1 upsampling vectors. By the upsampling operations, the feature map in the current residual block may have the same scale as the feature map in the previous residual block. Therefore, while the feature maps are enriched, adjacent feature maps may be used for fusion. In some examples, a feature vector corresponding to each residual block is fused with an upsampling vector of a feature vector corresponding to a subsequent residual block to obtain a fusion feature corresponding to each residual block. As an example, the fusion operation may be an addition operation or a subtraction operation between feature vectors. In some examples, a fusion feature of the circuit board image is determined according to the fusion features corresponding to the first residual block to the (n−1)th residual block.

At block 306, the first defect region is determined according to the fusion features by using a prediction network of the multi-scale detection network. In some examples, the prediction network includes a Region Proposal Network (RPN) and a Fast region with CNN Features (Fast R-CNN), which performs defect prediction according to fusion features and outputs the first defect region. The first defect region may be represented as a bounding box covering a portion of the circuit board image. Optionally, the prediction network may also output a classification result for the first defect region, for example, a first confidence of each pixel belonging to the defect in the first defect region.

In some embodiments, by performing convolution operations on a plurality of residual blocks, as the convolution operations belong to downsampling, image features of circuit board images with different scales may be naturally acquired. The closer a residual block is to the input layer, the more comprehensive information may be retained in its output, which is referred to as structural information. However, the closer a residual block is to the input layer, the stronger its output is in semantics, but the more structural information is lost. Therefore, by using the upsampling operations to fuse image features at various scales together, it may have the advantage of retaining both the semantic features of the circuit board image and the structural features of the circuit board, which is conducive to detecting a defect region under a scene feature of detecting the circuit board image, that is, with a large amount of image information but a small defect.

In some embodiments, the method of determining fusion features includes fusing the fusion features corresponding to the first residual block to the (n−1)th residual block to serve as a first fusion feature. This can fuse outputs of the various residual blocks into an overall feature. The method of determining fusion features further includes pooling a preset region in the first fusion feature as the fusion feature of the circuit board image. The preset region is a region that most likely has a defect. In some embodiments, the preset region is used to further narrow down a detection range, which can improve the real-time performance and accuracy.

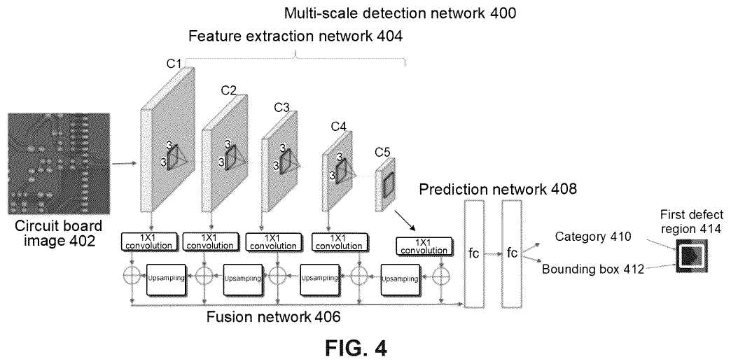

FIG. 4 is a schematic diagram of determining a first defect region by using a multi-scale detection network according to an embodiment of the present disclosure. As shown in FIG. 4, a multi-scale detection network 400 includes a feature extraction network 404, a fusion network 406, and a prediction network 408. The feature extraction network 404 includes five residual blocks, and the five residual blocks are residual blocks C1-C5, respectively.

The circuit board image 402 is input into an input layer of the multi-scale detection network 400, that is, the residual block C1, and a first feature map (not shown) is obtained through convolution. The first feature map is input into the residual block C2 to obtain a second feature map. The second feature map is input into the residual block C3 to obtain a third feature map. The third feature map is input into the residual block C4 to obtain a fourth feature map. The fourth feature map is input into the residual block C5 to obtain a fifth feature map. In the convolution process, the size of a convolution head may be set to 3×3, and after each convolution, the size of the feature map is reduced to half of the size before the convolution.

The five feature maps are input into the fusion network 406 below for fusion processing. In the fusion processing, the various feature maps are cascaded into feature vectors through a 1×1 convolution head. The fifth feature vector is upsampled and fused with (such as added to) the fourth feature vector to obtain the fusion feature corresponding to the fourth residual block. The fourth feature vector is upsampled and fused with the third feature vector to obtain the fusion feature corresponding to the third residual block. The third feature vector is upsampled and fused with the second feature vector to obtain the fusion feature corresponding to the second residual block. The second feature vector is upsampled and fused with the first feature vector to obtain the fusion feature corresponding to the first residual block. The fusion features corresponding to the first residual block to the fourth residual block are fused to obtain the first fusion feature.

The first fusion feature is input into the prediction network 408. The prediction network 408 includes an RPN and a Fast R-CNN. The RPN is used for determining a region of interest including a defect, and the Fast R-CNN is used for performing regression analysis on the region of interest to obtain the first defect region and its category. The RPN is shown in FIG. 4 as two network layers, but is not limited to this. After prediction, a category 410 and a bounding box 412 of the circuit board image 402 are determined. The category 410 indicates that a region within the bounding box 412 has a defect. The bounding box 412 covers a portion of the circuit board image 402 (only a local region is shown) to obtain the first defect region 414, wherein the bounding box 412 is indicated by a solid white line.

The present disclosure further provides an embodiment of training a multi-scale detection network. In an embodiment of training the multi-scale detection network, the total loss of the multi-scale detection network is determined according to the classification loss and region of interest loss of the RPN, as well as the classification loss and bounding box loss of the Fast R-CNN. Then, parameters of the RPN are adjusted according to the total loss. As an example, the classification loss of the RPN is calculated according to Equation (1) below:

$${L}_{cls} ( {p}_{i} , {p}_{i}^{*} ) = - log ( {p}_{i}^{*} \times {p}_{i} + ( 1 - {p}_{i}^{*} ) \times ( 1 - {p}_{i} ) ) \qquad ( 1 )$$

wherein i represents the index of an anchor box, that is, an output of each neuron in a fully connected layer used for prediction in the prediction network. The anchor box is a predefined rectangular box with a fixed size and aspect ratio. The function of the anchor box is generating a region of interest, that is, a rectangular box that may include a defect, pᵢ represents the probability of a defect in the anchor box i, pᵢ* represents a label, its content is a basic truth value, and L_{cls} represents the classification loss, where pᵢ* may be determined according to Equation (2) below:

$${p}_{i}^{*} = \{ \begin{matrix}0 & Negative sample \\ 1 & Positive sample\end{matrix} \qquad ( 2 )$$

In some examples, the classification loss of the Fast R-CNN is calculated according to Equation (3) below:

$${L}_{reg} ( {t}_{i} , {t}_{i}^{*} ) = R ( {t}_{i} - {t}_{i}^{*} ) \qquad ( 3 )$$

wherein tᵢ represents the offset between the coordinates of the region of interest and the coordinates of the anchor box i, tᵢ* represents the offset between the true value coordinates of the first region of interest and the coordinates of the anchor box i, and R represents the smooth loss function of L1 (Smooth L1). The multi-scale detection network trained according to Equation (1) to Equation (3) has good accuracy.

For block 206, the present disclosure further provides an embodiment of determining the second defect region by using a codec. The embodiment includes determining, according to the circuit board image, the standard image for the circuit board by using a codec. The codec may use a variety of standard images during training. Features of an input image are first extracted, then the standard image is reconstructed, and parameters of the codec are adjusted by comparing it with the input image. After training, the codec has the ability of reconstructing the standard image. The embodiment further includes determining a second defect region according to the circuit board image and the standard image. For example, subtraction may be performed on the standard image and the input image to determine the second defect region.

In the embodiment, the scene feature of detecting the circuit board is characterized by a large amount of image information and a small defect, it means that the input image is very similar to the standard image. Therefore, utilizing the scene feature, the codec trained with standard images can reconstruct the standard image according to the input circuit board image (with a defect), thereby determining the second defect region according to a difference between the two, and having high accuracy and real-time performance.

In some embodiments, the codec includes an encoder and a decoder, the encoder includes a plurality of concatenated network layers for encoding, and the decoder includes a plurality of concatenated network layers for decoding. The extraction and reconstruction process of the codec includes extracting image features from the circuit board image by using the encoder. The extraction and reconstruction process of the codec further includes reconstructing the standard image by using the decoder according to the image features of the circuit board image, wherein each network layer used for decoding performs decoding according to an output of the previous network layer and an output of the corresponding network layer used for encoding. In general, the deeper the network layer of the encoder, the more abstract the image features outputted thereby are, and the more structural information is lost. In some embodiments, the decoder, when reconstructing the standard image according to image features, absorbs more comprehensive structural information for the circuit board by reading the output of the corresponding network layer of the encoder, so that the standard image is more accurate, thereby improving the accuracy of the defect detection.

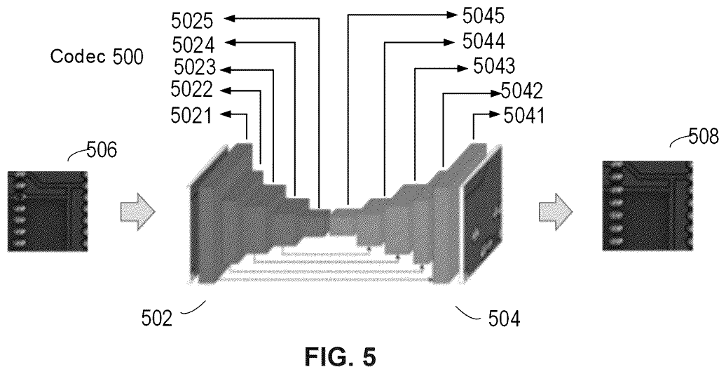

FIG. 5 is a schematic diagram of a codec according to an embodiment of the present disclosure. As shown in FIG. 5, a codec 500 includes an encoder 502 and a decoder 504. In the embodiment, the encoder 502 includes five network layers 5021 to 5025 for encoding, and these network layers 5021 to 5025 are connected in series. The decoder 504 includes five network layers 5045 to 5041 for decoding, and these network layers 5045 to 5041 are connected in series.

A circuit board image 506 is input to the input network layer 5021 of the encoder 502 of the codec 500. Starting from the input network layer 5021, it passes through the network layers 5022-5025 in sequence, and each network layer outputs a feature map. Then, the network layer 5025 transmits the output feature map to the network layer 5045 of the decoder 504. The network layer 5045 may directly start reconstruction according to the feature map output by the network layer 5025, and then transmit the reconstruction result to the network layer 5044. The network layer of the encoder corresponding to the network layer 5044 is the network layer 5024, and therefore, the network layer 5044 performs reconstruction according to the outputs of the network layer 5024 and the network layer 5045. Similarly, the network layer 5043 performs reconstruction according to the outputs of the network layer 5023 and the network layer 5044, the network layer 5042 performs reconstruction according to the outputs of the network layer 5022 and the network layer 5043, and the network layer 5041 performs reconstruction according to the outputs of the network layer 5021 and the network layer 5042 to obtain a standard image 508.

During the reconstruction process, each of the network layers used for decoding calculates the output of the previous the network layer and the output of the corresponding network layer used for encoding, and performs an adding operation on them to obtain a skip connection feature. The output is determined according to the skip connection feature. The codec 500 may calculate to obtain the standard image 508 and may subtract the standard image 508 from the input circuit board image 506, for example, by subtracting pixel by pixel to obtain the second defect region.

In some embodiments, in one type of defect region determined at block 204, one confidence (referred to as a “first confidence” herein) of each pixel representing a defect may be determined simultaneously. Similarly, in another type of defect region determined at block 206, another confidence of each pixel representing a defect may be determined simultaneously. In this case, a probability of a pixel representing a defect may be determined according to a weighted sum of the two confidences of the same pixel, thereby integrating information on the two types of defect regions. Determining the defect region of the circuit board further includes determining a set of pixels each having a probability greater than a preset threshold as the defect region. That is, the probability that a pixel belongs to the defect region=a preset first weight×the confidence in the first defect region+a preset second weight×the confidence in the second defect region. The preset first weight and the preset second weight may be specified artificially according to the accuracy of the first defect region and the second defect region. For example, the first weight may be preset to 0.7, and the second weight may be preset to 0.3. For a preset threshold, if the probability of a pixel is greater than the preset threshold, it indicates that the pixel represents the defect region; otherwise, the pixel is not sufficient to represent the defect region.

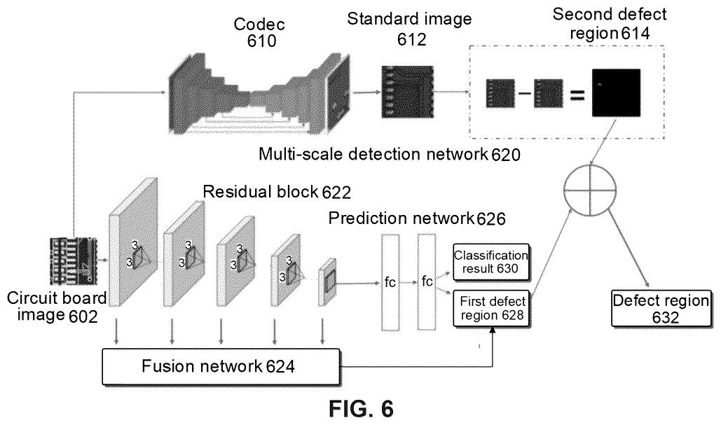

FIG. 6 is a schematic diagram of a method for detecting a circuit board defect according to an embodiment of the present disclosure. The upper part of FIG. 6 shows a codec 610, and the lower part of FIG. 6 shows a multi-scale detection network 620. In the embodiment shown in FIG. 6, a circuit board image 602 is input to the codec 610 and the multi-scale detection network 620, respectively. As an example, the codec 610 may be the same as the codec 500 in the above embodiment, including five network layers for encoding and five network layers for decoding. An input layer of the codec 610 receives the circuit board image 602 and calculates a feature map, and transmits the feature map to other network layers of an encoder. Each network layer outputs a feature map. Then, according to image features of the circuit board image, a decoder is used to reconstruct the standard image, wherein each network layer used for decoding performs decoding according to an output of a previous network layer and an output of a corresponding network layer used for encoding, so as to obtain a standard image 612. The codec 610 determines a second defect region 614 based on the standard image, wherein the minuend is the standard image 612, the subtrahend is the circuit board image 602 (that is, an input image), and to the right of the equal symbol is the second defect region 614, wherein the non-defective part is represented in black (that is, a pixel value of 0), and the pixel indicating a defect has a first confidence.

At the lower part of FIG. 6, the circuit board image 602 is input to the multi-scale detection network 620, and after passing through a plurality of residual blocks 622, feature maps at multiple scales are obtained. These feature maps are fused into a first fusion feature through a fusion network 624, and a pooling operation (such as average pooling) is performed on the first fusion feature at a region of interest. The pooling result is then transmitted to a prediction network 626 for prediction to obtain a classification result 630 and a bounding box, and the classification result 630 indicates a second confidence of each pixel within the bounding box. The bounding box covers a portion of the circuit board image 602 to obtain a first defect region 628. In the embodiment, it is assumed that a preset first weight is 0.7 and a preset second weight is 0.3. According to the first defect region 628, the second confidence, the second defect region 614, and the first confidence, a weighted sum of various pixels is determined, and a set of pixels each having a confidence greater than a preset threshold is determined as a defect region 632.

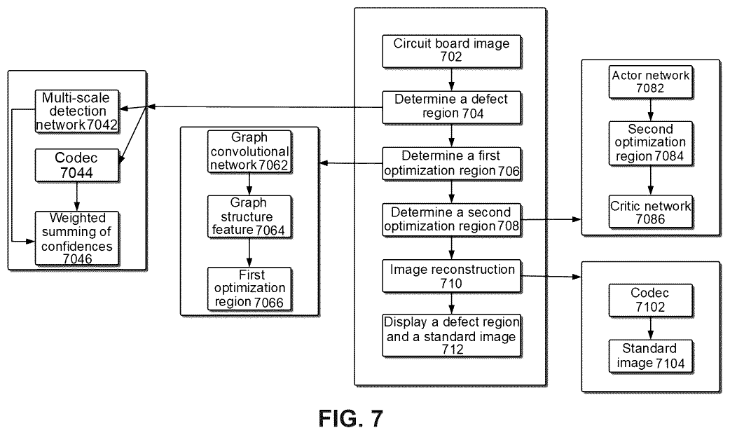

FIG. 7 is a schematic diagram of a method for detecting a circuit board defect according to an embodiment of the present disclosure. In the embodiment, a circuit board image 702 is input as an input image to a multi-scale detection network 7042 and a codec 7044, respectively, so as to obtain a first defect region and a second defect region. Weighted summing 7046 is performed on confidences of pixels in the two defect regions to obtain a defect region 704. The defect region 704 is transmitted to a graph convolutional network 7062 to determine a first optimization region 706. The graph convolutional network 7062 extracts a graph structure feature 7064 from the defect region 704, and then predicts to obtain a first optimization region 7066. The first optimization region 7066 is transmitted to an actor network 7082 to determine a second optimization region 708. An action of the actor network 7082 is set to determining a second optimization region 7084, and optionally, various defects in the second optimization region 7084 may also be listed. A critic network 7086 evaluates the action and provides an incentive signal to optimize the actor network 7082. Furthermore, image reconstruction 710 may be performed according to the second optimization region. The second optimization region 7084 may be transmitted to a codec 7102 (or the codec 7044) to determine its standard image 7104 according to the second optimization region. The defect region and the standard image are displayed at 712 for user reference.

The present disclosure also provides some embodiments of a method for detecting a circuit board defect, combined with any of the above embodiments, further including extracting a graph structure feature of the circuit board image from the defect region by using the graph convolutional networks. Nodes in the graph may represent various parts or components in the defect region, while edges may represent relationships or connections between these parts or components. Feature extraction is performed on a constructed graph structure by using the graph convolutional network. The graph convolutional network can capture complex relationships between nodes in the graph, thereby extracting graph structure features of the circuit board image. These features help gain a deeper understanding of the internal structure and relationships of the defect region.

Some embodiments further include determining a first optimization region of the circuit board image according to the graph structure features. According to the extracted graph structure features, the first optimization region of the circuit board image may be determined. The first optimization region has a defect in the circuit board, which is the optimization of the first defect region. In some embodiments, the circuit board is analyzed from the perspective of graph theory. For example, components of the circuit board may be considered as nodes, and connection lines between the components may be considered as edges. Therefore, the graph theory related technologies may be adapted to detect the circuit board, which is beneficial for improving the detection accuracy.

When the graph convolutional network is used, the convolution operation for each network layer may be calculated according to Equation (4) below:

$${h}_{v}^{( l + 1 )} = σ \times ( {\sum }_{u ∈ N ( v )} \frac{1}{\sqrt{{d}_{v} \times {d}_{u}}} \times {W}^{( l )} \times {h}_{u}^{( l )} + {B}^{( l )} \times {h}_{v}^{( l )} ) \qquad ( 4 )$$

wherein l represents the index of the network layer, v represents the index of a node l in the network layer, N(v) represents a set of neighboring nodes of a node v, dᵥ represents the degree of the node v, W^{(l)} and B^{(l)} both represent weight measures learned by the network layer l, and σ represents the nonlinear activation function.

The present disclosure further provides other embodiments of a method for detecting a circuit board defect, combined with any of the above embodiments for detecting a circuit board defect, further including determining a second optimization region by using an actor network according to the graph structure features. The actor network is a network used for decision-making, which may output an action according to the current graph structure features, that is, determine the second optimization region. The action is obtained through learning and analyzing the graph structure features. Some embodiments further include determining a defect in the second optimization region by using the actor network. By utilizing the actor network, the second optimization region of the circuit board image may be determined. At the same time, the actor network may further analyze specific defects in the second optimization region, such as listing the defects one by one through a driving list.

Some embodiments further include providing an incentive for the second optimization region by using a critic network. The critic network is a network used for evaluating the output of the actor network. It may provide an incentive signal according to the second optimization region determined by the actor network. The incentive signal may reflect the decision quality of the actor network and be used for adjusting and optimizing parameters of the actor network and the critic network. In some embodiments, the second optimization region is determined according to the first defect region, the second defect region, and the first optimization region, thereby further improving the accuracy of defect detection.

In some embodiments, the incentive may be calculated according to three factors: the number of defects detected by the actions of the actor network, the confidences of these defects, and the area of the second optimization region. As an example, the critic network calculates the incentive according to Equation (5) below:

$$r = α \times n + β \times c - γ \times a \qquad ( 5 )$$

wherein n represents the number of detected defects, c represents the average confidence of the detected defects, a represents the proportion of the second optimization region to the circuit board image, and α, β, and γ all represent hyperparameters used for balancing the incentive r.

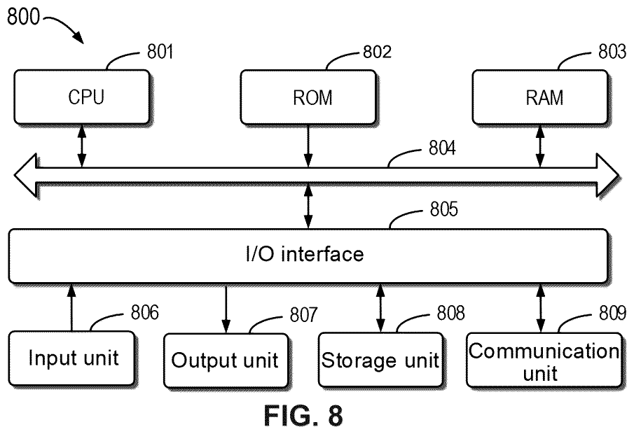

FIG. 8 shows a block diagram of an example device 800 that can be used to implement an embodiment of the present disclosure. As shown in the figure, the device 800 includes a computing unit 801, illustratively implemented as at least one central processing unit (CPU), which may execute various appropriate actions and processing according to computer program instructions stored in a read-only memory (ROM) 802 or computer program instructions loaded from a storage unit 808 into a random access memory (RAM) 803. Various programs and data required for the operation of the device 800 may also be stored in the RAM 803. The computing unit 801, the ROM 802, and the RAM 803 are connected to each other through a bus 804. An input/output (I/O) interface 805 is also connected to the bus 804.

A plurality of components in the device 800 are connected to the I/O interface 805, including: an input unit 806, such as a keyboard and a mouse; an output unit 807, such as various types of displays and speakers; the storage unit 808, such as a magnetic disk and an optical disc; and a communication unit 809, such as a network card, a modem, and a wireless communication transceiver. The communication unit 809 allows the device 800 to exchange information/data with other devices via a computer network, such as the Internet, and/or various telecommunication networks.

The computing unit 801 may be various general-purpose and/or special-purpose processing components with processing and computing capabilities. Some examples of the computing unit 801 include, but are not limited to, the above-noted one or more CPUs, graphics processing units (GPUs), various specialized artificial intelligence (AI) computing chips, various computing units for running machine learning model algorithms, digital signal processors (DSPs), and any appropriate processors, controllers, microcontrollers, etc. The computing unit 801 performs various methods and processes described above, such as the method 200. For example, in some embodiments, the method 200 may be implemented as a computer software program that is tangibly included in a machine-readable medium, such as the storage unit 808. In some embodiments, part or all of the computer program may be loaded and/or installed onto the device 800 via the ROM 802 and/or the communication unit 809. When the computer program is loaded to the RAM 803 and executed by the computing unit 801, one or more steps of the method 200 described above may be performed. Alternatively, in other embodiments, the computing unit 801 may be configured to implement the method 200 in any other suitable manner (such as by means of firmware).

The functions described herein may be executed at least in part by one or more hardware logic components. For example, without limitation, example types of available hardware logic components include: a Field Programmable Gate Array (FPGA), an Application Specific Integrated Circuit (ASIC), an Application Specific Standard Product (ASSP), a System on Chip (SOC), a Complex Programmable Logic Device (CPLD), and the like.

Program codes for implementing the method of the present disclosure may be written by using one programming language or any combination of a plurality of programming languages. The program code may be provided to a processor or controller of a general purpose computer, a special purpose computer, or another programmable data processing apparatus, such that the program code, when executed by the processor or controller, implements the functions/operations specified in the flow charts and/or block diagrams. The program code may be executed completely on a machine, executed partially on a machine, executed partially on a machine and partially on a remote machine as a stand-alone software package, or executed completely on a remote machine or server.

In the context of the present disclosure, a machine-readable medium may be a tangible medium that may include or store a program for use by an instruction execution system, apparatus, or device or in connection with the instruction execution system, apparatus, or device. The machine-readable medium may be a machine-readable signal medium or a machine-readable storage medium. The machine-readable medium may include, but is not limited to, an electronic, magnetic, optical, electromagnetic, infrared, or semiconductor system, apparatus, or device, or any suitable combination of the above content. More specific examples of the machine-readable storage medium may include one or more wire-based electrical connections, a portable computer diskette, a hard disk, a RAM, a ROM, an erasable programmable read-only memory (EPROM or flash memory), an optical fiber, a portable compact disc read-only memory (CD-ROM), an optical storage device, a magnetic storage device, or any suitable combinations thereof. Additionally, although operations are depicted in a particular order, this should not be construed as an indication that such operations are required to be performed in the particular order shown or in a sequential order, or that all illustrated operations should be performed to achieve desirable results. Under certain environments, multitasking and parallel processing may be advantageous. Likewise, although the above discussion contains several specific implementation details, these are not to be construed as limitations to the scope of the present disclosure. Certain features that are described in the context of separate embodiments may also be implemented in combination in a single implementation. Conversely, various features that are described in the context of a single implementation may also be implemented in a plurality of implementations separately or in any suitable sub-combination.

The computer-readable program instructions described herein may be downloaded from a computer-readable storage medium to various computing/processing devices, or downloaded to an external computer or external storage device via a network, such as the Internet, a local area network, a wide area network, and/or a wireless network. The network may include copper transmission cables, fiber optic transmission, wireless transmission, routers, firewalls, switches, gateway computers, and/or edge servers. A network adapter card or network interface in each computing/processing device receives computer-readable program instructions from a network and forwards the computer-readable program instructions for storage in a computer-readable storage medium in each computing/processing device.

The computer program instructions for performing the operations of the present disclosure may be assembly instructions, instruction set architecture (ISA) instructions, machine instructions, machine-related instructions, microcode, firmware instructions, state setting data, or source code or object code written in any combination of one or more programming languages, wherein the programming languages include object-oriented programming languages such as Smalltalk and C++, and conventional procedural programming languages such as the C language or similar programming languages. The computer-readable program instructions may be executed entirely on a user computer, partly on a user computer, as a stand-alone software package, partly on a user computer and partly on a remote computer, or entirely on a remote computer or a server. In a case where a remote computer is involved, the remote computer can be connected to a user computer through any kind of networks, including a local area network (LAN) or a wide area network (WAN), or can be connected to an external computer (for example, connected through the Internet using an Internet service provider). In some embodiments, an electronic circuit, such as a programmable logic circuit, a field programmable gate array (FPGA), or a programmable logic array (PLA), is customized by utilizing status information of the computer-readable program instructions. The electronic circuit may execute the computer-readable program instructions so as to implement various aspects of the present disclosure.

Various aspects of the present disclosure are described herein with reference to flow charts and/or block diagrams of the method, the apparatus (system), and the computer program product according to embodiments of the present disclosure. It should be understood that each block of the flow charts and/or the block diagrams and combinations of blocks in the flow charts and/or the block diagrams may be implemented by the computer-readable program instructions.

These computer-readable program instructions may be provided to a processing unit of a general-purpose computer, a special-purpose computer, or other programmable data processing apparatuses to produce a machine, such that these instructions, when executed by the processing unit of the computer or other programmable data processing apparatuses, produce means for implementing the functions/acts specified in one or more blocks in the flow charts and/or block diagrams. These computer-readable program instructions may also be stored in a computer-readable storage medium, and these instructions cause a computer, a programmable data processing apparatus, and/or other devices to operate in a specific manner; and thus the computer-readable medium having instructions stored thereon includes an article of manufacture that includes instructions that implement various aspects of the functions/actions specified in one or more blocks in the flow charts and/or block diagrams.

The computer-readable program instructions may also be loaded onto a computer, other programmable data processing apparatuses, or other devices, such that a series of operational steps are performed on the computer, other programmable data processing apparatuses, or other devices to produce a computer-implemented process, such that the instructions executed on the computer, other programmable data processing apparatuses, or other devices implement the functions/actions specified in one or more blocks in the flow charts and/or block diagrams.

The flow charts and block diagrams in the drawings illustrate the architectures, functions, and operations of possible implementations of the systems, methods, and computer program products according to various embodiments of the present disclosure. In this regard, each block in the flow charts or block diagrams may represent a module, a program segment, or part of an instruction, the module, program segment, or part of an instruction including one or more executable instructions for implementing specified logical functions. In some alternative implementations, functions marked in the blocks may also occur in an order different from that marked in the accompanying drawings. For example, two successive blocks may actually be executed in parallel substantially, and sometimes they may also be executed in a reverse order, which depends on the involved functions. It should be further noted that each block in the block diagrams and/or flow charts as well as a combination of blocks in the block diagrams and/or flow charts may be implemented using a dedicated hardware-based system that executes specified functions or actions, or using a combination of special hardware and computer instructions.

Various embodiments of the present disclosure have been described above. The above description is illustrative, rather than exhaustive, and is not limited to the disclosed various embodiments. Numerous modifications and alterations will be apparent to persons of ordinary skill in the art without departing from the scope and spirit of the illustrated embodiments. The selection of terms used herein is intended to best explain the principles and practical applications of the various embodiments and their associated technical improvements, so as to enable persons of ordinary skill in the art to understand the embodiments disclosed herein.

What is claimed is:

1. A method comprising:
acquiring a circuit board image of a circuit board;
determining a first defect region according to the circuit board image, wherein the first defect region indicates a location of a defect in the circuit board;
determining a second defect region according to the circuit board image and a standard image for the circuit board, wherein the second defect region indicates a location of a defect in the circuit board, and the standard image indicates a circuit board without any defect; and
determining a defect region of the circuit board according to the first defect region and the second defect region.

2. The method according to claim 1, wherein determining the first defect region according to the circuit board image comprises:
determining feature maps at multiple scales of the circuit board image by using a feature extraction network of a multi-scale detection network;
determining fusion features of the feature maps at the multiple scales by using a fusion network of the multi-scale detection network; and
determining, according to the fusion features, the first defect region by using a prediction network of the multi-scale detection network.

3. The method according to claim 2, wherein the feature extraction network comprises n concatenated residual blocks, each of the residual blocks comprises at least one convolutional layer, n is a positive integer greater than 1, and determining the feature maps at the multiple scales of the circuit board image by using the feature extraction network comprises:
determining n feature maps of the circuit board image by using the n concatenated residual blocks to serve as the feature maps at the multiple scales, wherein each of the feature maps is an output of the corresponding residual block.

4. The method according to claim 3, wherein an input layer of the feature extraction network is comprised in a first residual block, and determining the fusion features of the feature maps at the multiple scales by using the fusion network comprises:
cascading each of the feature maps into a feature vector through a convolutional operation;
upsampling a second feature vector to an nth feature vector to serve as n−1 upsampling vectors;
fusing a feature vector corresponding to each residual block with an upsampling vector of a feature vector corresponding to a subsequent residual block, to serve as a fusion feature corresponding to each residual block; and
determining a fusion feature of the circuit board image according to the fusion features corresponding to the first residual block to an (n−1)th residual block.

5. The method according to claim 4, wherein determining the fusion feature of the circuit board image according to the fusion features corresponding to the first residual block to the (n−1)th residual block comprises:
fusing the fusion features corresponding to the first residual block to the (n−1)th residual block to serve as a first fusion feature; and
pooling a region in the first fusion feature to serve as the fusion feature of the circuit board image.

6. The method according to claim 1, wherein determining the second defect region according to the circuit board image and the standard image for the circuit board comprises:
determining the standard image for the circuit board by using a codec according to the circuit board image; and
determining the second defect region according to the circuit board image and the standard image.

7. The method according to claim 6, wherein the codec comprises an encoder and a decoder, the encoder comprises a plurality of concatenated network layers for encoding, the decoder comprises a plurality of concatenated network layers for decoding, and determining the standard image for the circuit board by using the codec according to the circuit board image comprises:
extracting an image feature of the circuit board image by using the encoder; and
reconstructing, according to the image feature of the circuit board image, the standard image by using the decoder, wherein each of the concatenated network layers used for decoding performs decoding according to an output of a previous network layer and an output of a corresponding network layer used for encoding.

8. The method according to claim 1, wherein each pixel in the first defect region has a first confidence, each pixel in the second defect region has a second confidence, and determining the defect region of the circuit board according to the first defect region and the second defect region comprises:
determining a weighted sum of the first confidence and the second confidence for each pixel according to a first weight and a second weight, to serve as a probability of each pixel belonging to a defect; and
determining a set of pixels each having a probability greater than a threshold as the defect region.

9. The method according to claim 1, further comprising:
extracting a graph structure feature of the circuit board image from the defect region by using a graph convolutional network; and
determining a first optimization region of the circuit board image according to the graph structure feature.

10. The method according to claim 9, further comprising:
determining a second optimization region by using an actor network according to the graph structure feature;
determining a defect in the second optimization region by using the actor network; and
providing an incentive for the second optimization region by using a critic network.

11. An electronic device, comprising:
at least one processor; and
a memory coupled to the at least one processor and having instructions stored therein, wherein the instructions, when executed by the at least one processor, cause the electronic device to perform actions comprising:
acquiring a circuit board image of a circuit board;
determining a first defect region according to the circuit board image, wherein the first defect region indicates a location of a defect in the circuit board;
determining a second defect region according to the circuit board image and a standard image for the circuit board, wherein the second defect region indicates a location of a defect in the circuit board, and the standard image indicates a circuit board without any defect; and
determining a defect region of the circuit board according to the first defect region and the second defect region.

12. The electronic device according to claim 11, wherein determining the first defect region according to the circuit board image comprises:
determining feature maps at multiple scales of the circuit board image by using a feature extraction network of a multi-scale detection network;
determining fusion features of the feature maps at the multiple scales by using a fusion network of the multi-scale detection network; and
determining, according to the fusion features, the first defect region by using a prediction network of the multi-scale detection network.

13. The electronic device according to claim 12, wherein the feature extraction network comprises n concatenated residual blocks, each residual block comprises at least one convolutional layer, n is a positive integer greater than 1, and determining the feature maps at the multiple scales of the circuit board image by using the feature extraction network comprises:
determining n feature maps of the circuit board image by using the n concatenated residual blocks to serve as the feature maps at the multiple scales, wherein each feature map is an output of the corresponding residual block.

14. The electronic device according to claim 13, wherein an input layer of the feature extraction network is comprised in a first residual block, and determining the fusion features of the feature maps at the multiple scales by using the fusion network comprises:
cascading each feature map into a feature vector through a convolutional operation;
upsampling a second feature vector to an nth feature vector to serve as n−1 upsampling vectors;
fusing a feature vector corresponding to each residual block with an upsampling vector of a feature vector corresponding to a subsequent residual block, to serve as a fusion feature corresponding to each residual block; and
determining a fusion feature of the circuit board image according to the fusion features corresponding to the first residual block to an (n−1)th residual block.

15. The electronic device according to claim 14, wherein determining the fusion feature of the circuit board image according to the fusion features corresponding to the first residual block to the (n−1)th residual block comprises:
fusing the fusion features corresponding to the first residual block to the (n−1)th residual block to serve as a first fusion feature; and
pooling a region in the first fusion feature to serve as the fusion feature of the circuit board image.

16. The electronic device according to claim 11, wherein determining the second defect region according to the circuit board image and the standard image for the circuit board comprises:
determining the standard image for the circuit board by using a codec according to the circuit board image; and
determining the second defect region according to the circuit board image and the standard image.

17. The electronic device according to claim 16, wherein the codec comprises an encoder and a decoder, the encoder comprises a plurality of concatenated network layers for encoding, the decoder comprises a plurality of concatenated network layers for decoding, and determining the standard image for the circuit board by using the codec according to the circuit board image comprises:
extracting an image feature of the circuit board image by using the encoder; and
reconstructing, according to the image feature of the circuit board image, the standard image by using the decoder, wherein each network layer used for decoding performs decoding according to an output of a previous network layer and an output of a corresponding network layer used for encoding.

18. The electronic device according to claim 11, wherein each pixel in the first defect region has a first confidence, each pixel in the second defect region has a second confidence, and determining the defect region of the circuit board according to the first defect region and the second defect region comprises:
determining a weighted sum of the first confidence and the second confidence for each pixel according to a first weight and a second weight, to serve as a probability of each pixel belonging to a defect; and
determining a set of pixels each having a probability greater than a threshold as the defect region.

19. The electronic device according to claim 11, wherein the actions further comprise:
extracting a graph structure feature of the circuit board image from the defect region by using a graph convolutional network; and
determining a first optimization region of the circuit board image according to the graph structure feature.

20. A computer program product, the computer program product being tangibly stored on a non-transitory computer-readable medium and comprising machine-executable instructions, wherein the machine-executable instructions, when executed by a machine, cause the machine to perform actions comprising:
acquiring a circuit board image of a circuit board;
determining a first defect region according to the circuit board image, wherein the first defect region indicates a location of a defect in the circuit board;
determining a second defect region according to the circuit board image and a standard image for the circuit board, wherein the second defect region indicates a location of a defect in the circuit board, and the standard image indicates a circuit board without any defect; and
determining a defect region of the circuit board according to the first defect region and the second defect region.
